(19) United States
(12) Patent Application Publication
(10) Pub. No.: US 2026/0018193 A1
(43) Pub. Date: Jan. 15, 2026

(54) MEMORY CELL AND NON-VOLATILE MEMORY DEVICE

(71) Applicant: eMemory Technology Inc., Hsinchu (TW)

(72) Inventors: Chih-Hsin CHEN, Hsinchu County (TW); Tsung-Mu LAI, Hsinchu County (TW); Chun-Yuan LO, Hsinchu County (TW)

(21) Appl. No.: 19/241,409

(22) Filed: Jun. 18, 2025

Related U.S. Application Data
(60) Provisional application No. 63/671,307, filed on Jul. 15, 2024.

(51) Int. Cl. G11C 5/06; G11C 11/419; H10B 10/00

(52) U.S. Cl. CPC G11C 5/063; G11C 11/419; H10B 10/12

(57) ABSTRACT

A memory cell includes a first transistor, a second transistor, and a third transistor. A body terminal of the first transistor is connected to an erase line. A first source/drain terminal of the first transistor is connected to a program line. Body terminals of the second transistor and the third transistor are connected to a control line. A first source/drain terminal of the second transistor is connected to a bit line. A gate terminal of the second transistor is connected to a gate terminal of the first transistor. A first source/drain terminal of the third transistor is connected to the control line. A second source/drain terminal of the third transistor is connected to a second source/drain terminal of the second transistor. A gate terminal of the third transistor is connected to a word line. The gate terminals of the first transistor and second transistor are floating.

### RELATED APPLICATIONS

This application claims priority to U.S. Provisional Application Ser. No. 63/671,307, filed Jul. 15, 2024, which is herein incorporated by reference.

### BACKGROUND

### Technical Field

The present disclosure relates to memory technology. More particularly, the present disclosure relates to a memory cell and non-volatile memories with advantages of size reduction, endurance improvement, low-voltage read operation, and other read benefits.

### Description of Related Art

With developments of technology, various memories are developed. In some related approaches, memory cells in the memories are larger in size, suffer from high voltage stress, and have poor reading reliability.

### SUMMARY

Some aspects of the present disclosure are to a memory cell. The memory cell includes a first transistor, a second transistor, and a third transistor. The first transistor includes a body terminal, a first source/drain terminal, a second source/drain terminal, and a gate terminal. The body terminal of the first transistor is connected to an erase line. The first source/drain terminal of the first transistor is connected to a program line. The second transistor includes a body terminal, a first source/drain terminal, a second source/drain terminal, and a gate terminal. The body terminal of the second transistor is connected to a control line. The first source/drain terminal of the second transistor is connected to a bit line. The gate terminal of the second transistor is connected to the gate terminal of the first transistor. The third transistor includes a body terminal, a first source/drain terminal, a second source/drain terminal, and a gate terminal. The body terminal of the third transistor is connected to the control line. The first source/drain terminal of the third transistor is connected to the control line. The second source/drain terminal of the third transistor is connected to the second source/drain terminal of the second transistor. The gate terminal of the third transistor is connected to a word line. The gate terminal of the first transistor and the gate terminal of the second transistor are floating. When a program operation is performed on the memory cell, a plurality of electrons are injected from the body terminal of the first transistor into the gate terminal of the first transistor. When a read operation is performed on the memory cell, the first source/drain terminal of the second transistor provides a read current to the bit line.

Some aspects of the present disclosure are to provide a non-volatile memory device. The non-volatile memory device includes a first well region, a second well region, a third well region, and a plurality of memory cells. Each memory cell includes a first transistor, a second transistor, and a third transistor. A gate terminal of the first transistor and a gate terminal of the second transistor are mutually coupled and are floating, and the second transistor and the third transistor are coupled in series. A first memory cell of the plurality of memory cells is in a first page and a second memory cell of the plurality of memory cells is in a second page. The first transistor in the first memory cell is disposed on the first well region, and the second transistor and the third transistor in the first memory cell are disposed on the second well region. The first transistor in the second memory cell is disposed on the third well region, and the second transistor and the third transistor in the second memory cell are disposed on the second well region.

Some aspects of the present disclosure are to provide a non-volatile memory device. The non-volatile memory device includes a common deep region, a well region, and a plurality of memory cells. The well region is disposed in the common deep region. Each memory cell comprises a first transistor, a second transistor, and a third transistor. A gate terminal of the first transistor and a gate terminal of the second transistor are mutually coupled and are floating, and the second transistor and the third transistor are coupled in series. A first memory cell of the plurality of memory cells is in a first page and a second memory cell of the plurality of memory cells is in a second page. The first transistor in the first memory cell is disposed on the common deep region, and the second transistor and the third transistor in the first memory cell are disposed on the well region. The first transistor in the second memory cell is disposed on the common deep region, and the second transistor and the third transistor in the second memory cell are disposed on the well region.

### BRIEF DESCRIPTION OF THE DRAWINGS

The disclosure can be more fully understood by reading the following detailed description of the embodiment, with reference made to the accompanying drawings as follows:

FIG. 1 is a schematic diagram illustrating a memory cell according to some embodiments of the present disclosure.

FIG. 2A is a schematic diagram illustrating a non-volatile memory device without a common deep region according to some embodiments of the present disclosure.

FIG. 2B is a layout diagram illustrating the non-volatile memory device in FIG. 2A according to some embodiments of the present disclosure.

FIG. 3A is a schematic diagram illustrating a non-volatile memory device with a common deep region according to some embodiments of the present disclosure.

FIG. 3B is a layout diagram illustrating the non-volatile memory device in FIG. 3A according to some embodiments of the present disclosure.

FIG. 4 is a schematic diagram illustrating an erase operation and an erase inhibit operation on the memory cell in FIG. 1 according to some embodiments of the present disclosure.

FIG. 5 is a schematic diagram illustrating a program operation and a program inhibit operation on the memory cell in FIG. 1 according to some embodiments of the present disclosure.

FIG. 6 is a schematic diagram illustrating voltages under different operations on the non-volatile memory device without the common deep region in FIG. 2A according to some embodiments of the present disclosure.

FIG. 7 is a schematic diagram illustrating an erase operation and an erase inhibit operation on the non-volatile memory device without the common deep region in FIG. 2A according to some embodiments of the present disclosure.

FIG. 8 is a schematic diagram illustrating a program operation and a program inhibit operation on the non-volatile memory device without the common deep region in FIG. 2A according to some embodiments of the present disclosure.

FIG. 9 is a schematic diagram illustrating a read operation and a read inhibit operation on the non-volatile memory device without the common deep region in FIG. 2A according to some embodiments of the present disclosure.

FIG. 10 is a schematic diagram illustrating voltages under different operations on the non-volatile memory device with the common deep region in FIG. 3A according to some embodiments of the present disclosure.

FIG. 11 is a schematic diagram illustrating an erase operation and an erase inhibit operation on the non-volatile memory device with the common deep region in FIG. 3A according to some embodiments of the present disclosure.

FIG. 12 is a schematic diagram illustrating a program operation and a program inhibit operation on the non-volatile memory device with the common deep region in FIG. 3A according to some embodiments of the present disclosure.

FIG. 13 is a schematic diagram illustrating a read operation and a read inhibit operation on the non-volatile memory device with the common deep region in FIG. 3A according to some embodiments of the present disclosure.

### DETAILED DESCRIPTION

In the present disclosure, “connected” or “coupled” may refer to “electrically connected” or “electrically coupled.” “Connected” or “coupled” may also refer to operations or actions between two or more elements.

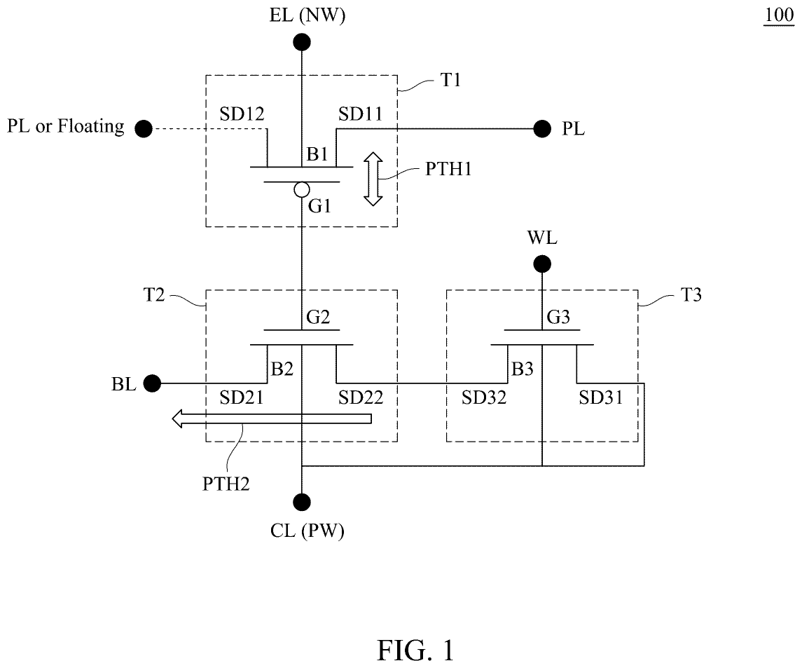

Reference is made to FIG. 1. FIG. 1 is a schematic diagram illustrating a memory cell 100 according to some embodiments of the present disclosure. The memory cell 100 can be disposed in a non-volatile multi-time program (MTP) memory.

As illustrated in FIG. 1, the memory cell 100 includes a transistor T1, a transistor T2, and a transistor T3. The transistor T1 is connected to the transistor T2, and the transistor T2 is connected to the transistor T3. The transistor T1 is a p-type transistor, and the transistor T2 and the transistor T3 are n-type transistors.

The transistor T1 includes a body terminal B1, a first source/drain terminal SD11, a second source/drain terminal SD12, and a gate terminal G1. The transistor T2 includes a body terminal B2, a first source/drain terminal SD21, a second source/drain terminal SD22, and a gate terminal G2. The transistor T3 includes a body terminal B3, a first source/drain terminal SD31, a second source/drain terminal SD32, and a gate terminal G3.

The body terminal B1 of the transistor T1 is connected to an erase line EL and is disposed on an n-well region NW. The first source/drain terminal SD11 of the transistor T1 is connected to a program line PL. The second source/drain terminal SD12 of the transistor T1 is connected to the program line PL or is floating.

The body terminal B2 of the transistor T2 is connected to a control line CL and is disposed on a p-well region PW. The first source/drain terminal SD21 of the transistor T2 is connected to a bit line BL. The gate terminal G2 of the transistor T2 is connected to the gate terminal G1 of the transistor T1, where the gate terminal G1 and the gate terminal G2 are floating.

The body terminal B3 of the transistor T3 is connected to the control line CL and is disposed on the p-well region PW. The first source/drain terminal SD31 of the transistor T3 is connected to the control line CL. The second source/drain terminal SD32 of the transistor T3 is connected to the second source/drain terminal SD22 of the transistor T2. The gate terminal G3 of the transistor T3 is connected to a word line WL. Accordingly, the gate terminal G1 of the transistor T1 and the gate terminal G2 of the transistor T2 are mutually coupled and are floating, and the transistor T2 and the transistor T3 are coupled in series.

In some related approaches, the memory cell is disposed on more than two well regions, and includes different paths (or elements) for erasing and programming.

Compared to the related approaches above, in the present disclosure, the memory cell 100 is disposed on only two well regions (i.e., one n-well region NW and one p-well region PW) and has a common path (or element) for erasing and programming so as to reduce the cell size.

In addition, compared to the related approaches above, in the present disclosure, the gate terminal G2 of the transistor T2 is merely connected to one element (i.e. the transistor T1), so the coupling ratio of the transistor T2 to the transistor T1 is higher.

As illustrated in FIG. 1, an erase/program path PTH1 is for an erase operation and a program operation on the memory cell 100, and a read path PTH2 is for a read operation on the memory cell 100. That is, when the read operation is performed on the memory cell 100, the first source/drain terminal SD21 of the transistor T2 provides a read current to the bit line BL.

In some related approaches, the memory cell is programmed and read through a floating gate transistor thereof (i.e., through the same path), so the read reliability of the memory cell is adversely affected by the high-voltage stress the floating gate transistor suffers. In addition, in some related approaches, all transistors T1-T3 are implemented by I/O devices.

Compared to the related approaches above, in the present disclosure, only the read path PTH2 is on the transistor T2 (i.e., the floating gate transistor). This can protect the transistor T2 (i.e., the floating gate transistor) from suffering from the high-voltage stress. In addition, since the transistor T3 is only for the read operation, the transistor T3 can be implemented by a core device (having a lower threshold voltage) instead of an I/O device (having a higher threshold voltage) to reduce read power while only the transistors T1-T2 are implemented by I/O devices.

In addition, in the present disclosure, the erase/program path PTH1 and the read path PTH2 are separated, so transistor degradation can be suppressed so as to improve endurance.

Furthermore, this design keeps some benefits. For example, this design is with a larger current sensing window and an excellent retention on the program operation.

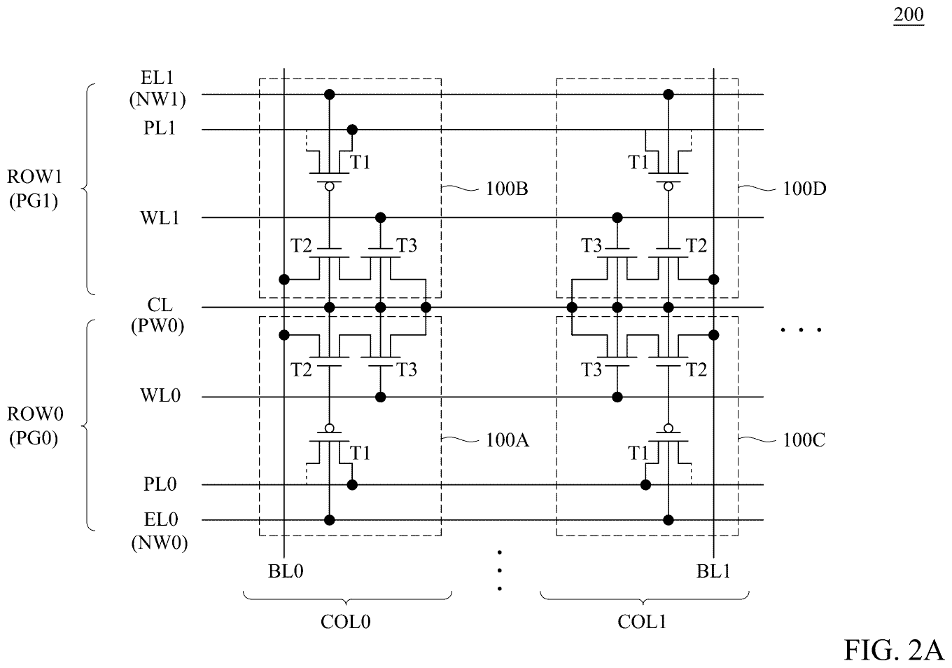

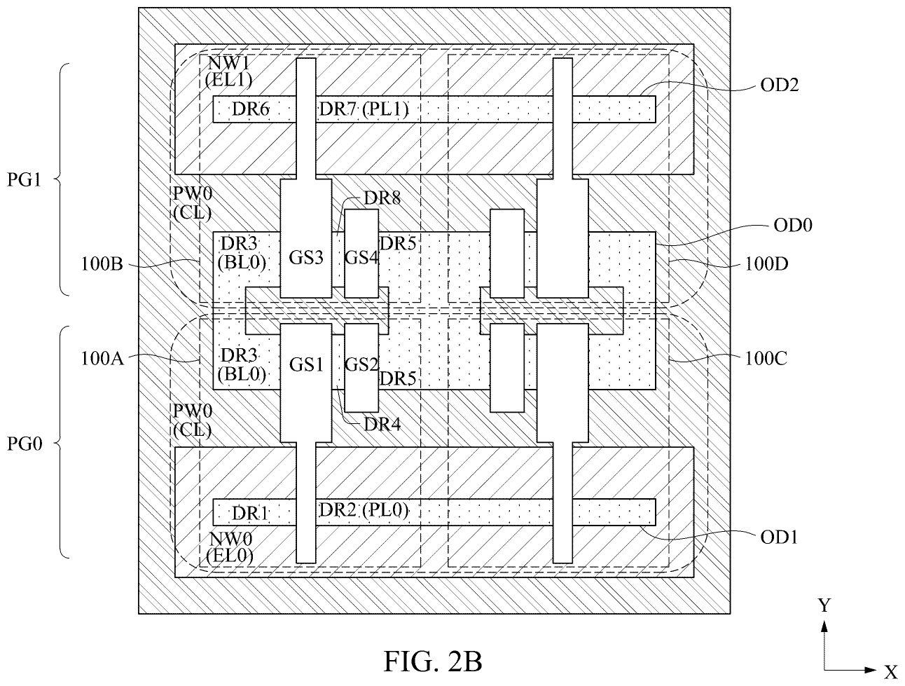

References are made to FIG. 1, FIG. 2A, and FIG. 2B. FIG. 2A is a schematic diagram illustrating a non-volatile memory device 200 without a common deep region according to some embodiments of the present disclosure. FIG. 2B is a layout diagram illustrating the non-volatile memory device 200 in FIG. 2A according to some embodiments of the present disclosure.

As illustrated in FIG. 2A, the non-volatile memory device 200 includes multiple memory cells 100A, 100B, 100C, and 100D, a p-well region PW0, n-well regions NW0 and NW1, and active regions OD0, OD1, and OD2 (shown in FIG. 2B). For better understanding, FIG. 2A merely illustrates four memory cells 100A-100D, but the present disclosure is not limited to this quantity. The memory cells 100A-100D are arranged in an array form.

The memory cells 100A and 100B in a column COL0 are connected to a bit line BL0, and the memory cells 100C and 100D in a column COL1 are connected to a bit line BL1. The memory cells 100A and 100C in a row ROW0 are in a page PG0, and the memory cells 100B and 100D in a row ROW1 are in a page PG1. The memory cells 100A and 100C in the row ROW0 are connected to an erase line EL0, a program line PL0, a word line WL0, and a control line CL. The memory cells 100B and 100D in the row ROW1 are connected to an erase line EL1, a program line PL1, a word line WL1, and the control line CL.

Each of the memory cells 100A-100D includes the transistors T1-T3. The transistor T1 of the memory cell 100A is disposed on the n-well region NW0 connected to the erase line EL0. The transistors T2-T3 of the memory cell 100A are disposed on the p-well region PW0 connected to the control line CL. The transistor T1 of the memory cell 100B is disposed on the n-well region NW1 connected to the erase line EL1. The transistors T2-T3 of the memory cell 100B are disposed on the p-well region PW0 connected to the control line CL. In other words, the memory cell 100A and the memory cell 100B share the p-well region PW0 (i.e., connected to the same control line CL).

The memory cells 100C and 100D have the similar circuit architectures, so they are not described herein again.

Other details about internal architectures of each of the memory cells 100A-100D are the same to those of the memory cell 100 in FIG. 1, so they are not described herein again.

As illustrated in FIG. 2B, the n-well region NW0, the active region OD0 and the n-well region NW1 are arranged in sequence along a direction Y, and are disposed in the p-well region PW0. The active regions OD1 and OD2 are respectively disposed in the n-well regions NW0 and NW1. The n-well regions NW0 and NW1 and the active regions OD0, OD1, and OD2 are extended along a direction X. In addition, the active region OD0 is n-doped and the active regions OD1 and OD2 are p-doped. A gate structure GS1 is disposed on the active regions OD0 and OD1, the n-well region NW0, and the p-well region PW0, where the gate structure GS1 is floating. A first part of the gate structure GS1 extends along the direction Y, and partially covers the active region OD0 and the p-well region PW0. A second part of the gate structure GS1 extends along the direction Y, and partially covers the p-well region PW0, the n-well region NW0 and the active region OD1. The first part of the gate structure GS1 has a greater width in comparison with the second part of the gate structure GS1, where the widths of the first part and the second part of the gate structure GS1 are measured along the direction X (i.e., a lateral direction of the n-well region NW0). A gate structure GS2 is disposed on the p-well region PW0 and the active region OD0, where the gate structure GS2 is connected to the word line WL0. The active region OD1 is divided into doping regions DR1 and DR2 by the second part of the gate structure GS1. The doping region DR1 is disposed in the n-well region NW0 and at a first side of the second part of the gate structure GS1, where the doping region DR1 is floating or connected to the program line PL0. The doping region DR2 is disposed in the n-well region NW0 and at a second side of the second part of the gate structure GS1, where the doping region DR2 is connected to the program line PL0. The active region OD0 is divided into doping regions DR3, DR4, and DR5 by the first part of the gate structure GS1 and the second gate structure GS2. The doping region DR3 is disposed in the p-well region PW0 and at the first side of the first part of the gate structure GS1, where the doping region DR3 is connected to the bit line BL0. The doping region DR4 is disposed in the p-well region PW0 and between the second side of the first part of the gate structure GS1 and a first side of the gate structure GS2. A doping region DR5 is disposed in the p-well region PW0 and at a second side of the gate structure GS2, where the doping region DR5 is connected to the control line CL via the p-well region PW0.

The second part of the gate structure GS1, the doping region DR1, and the doping region DR2 form the transistor T1 in the memory cell 100A. The first part of the gate structure GS1, the doping region DR3, and the doping region DR4 form the transistor T2 in the memory cell 100A. The gate structure GS2, the doping region DR4, and the doping region DR5 form the transistor T3 in the memory cell 100A. That is, the gate length of the transistor T1 is smaller than the gate length of the transistor T2.

A gate structure GS3 is disposed on the active regions OD0 and OD2, the n-well region NW1 and the p-well region PW0, where the gate structure GS3 is floating. A first part of the gate structure GS3 extends along the direction Y, and partially covers the active region OD0 and the p-well region PW0. A second part of the gate structure GS3 extends along the direction Y, and partially covers the p-well region PW0, the n-well region NW1 and the active region OD2. The first part of the gate structure GS3 has a greater width in comparison with the second part of the gate structure GS3, where the widths of the first part and the second part of the gate structure GS3 are measured along the direction X (i.e., a lateral direction of the n-well region NW1). A gate structure GS4 is disposed on the p-well region PW0 and the active region OD0. The active region OD2 is divided into doping regions DR6 and DR7 by the second part of the gate structure GS3. The doping region DR6 is disposed in the n-well region NW1 and at a first side of the second part of the gate structure GS3, wherein the doping region DR6 is floating or connected to the program line PL1. The doping region DR7 is disposed in the n-well region NW1 and at a second side of the second part of the gate structure GS3, wherein the doping region DR7 is connected to the program line PL1. The active region OD0 is divided into doping regions DR3, DR8, and DR5 by the first part of the gate structure GS3 and the second gate structure GS4. In addition, the doping region DR3 is also disposed at the first side of the first part of the gate structure GS3. The doping region DR8 is disposed in the p-well region PW0 and between the second side of the first part of the gate structure GS3 and a first side of the gate structure GS4. In addition, the doping region DR5 is also disposed at a second side of the gate structure GS4.

The second part of the gate structure GS3, the doping region DR6, and the doping region DR7 form the transistor T1 in the memory cell 100B. The first part of the gate structure GS3, the doping region DR3, and the doping region DR8 form the transistor T2 in the memory cell 100B. The gate structure GS4, the doping region DR8, and the doping region DR5 form the transistor T3 in the memory cell 100B. That is, the gate length of the transistor T1 is smaller than the gate length of the transistor T2.

The memory cells 100C and 100D have similar layout architectures, so they are not described herein again.

In some related approaches, each page is connected to the control line and the erase line via two different n-well regions. Different pages neither share their control lines nor their erase lines. Therefore, there is a wasted space between two adjacent n-well regions (e.g., two adjacent erase lines EL) of the memory cells in different pages.

Compared to the related approaches above, in the present disclosure, the memory cells 100A and 100C in the page PG0 and the memory cells 100B and 100D in the page PG1 share the p-well regions PW0 to share the control line CL. Moreover, the transistors T1-T3 of different pages are arranged in a mirror configuration between the n-well region NW0 (i.e., the erase line EL0) and the n-well region NW1 (i.e., the erase line EL1). Therefore, there is no wasted space between the two adjacent n-well region NW0 (i.e., the erase line EL0) and the n-well region NW1 (i.e., the erase line EL1). Thus, a more compacted array can be achieved.

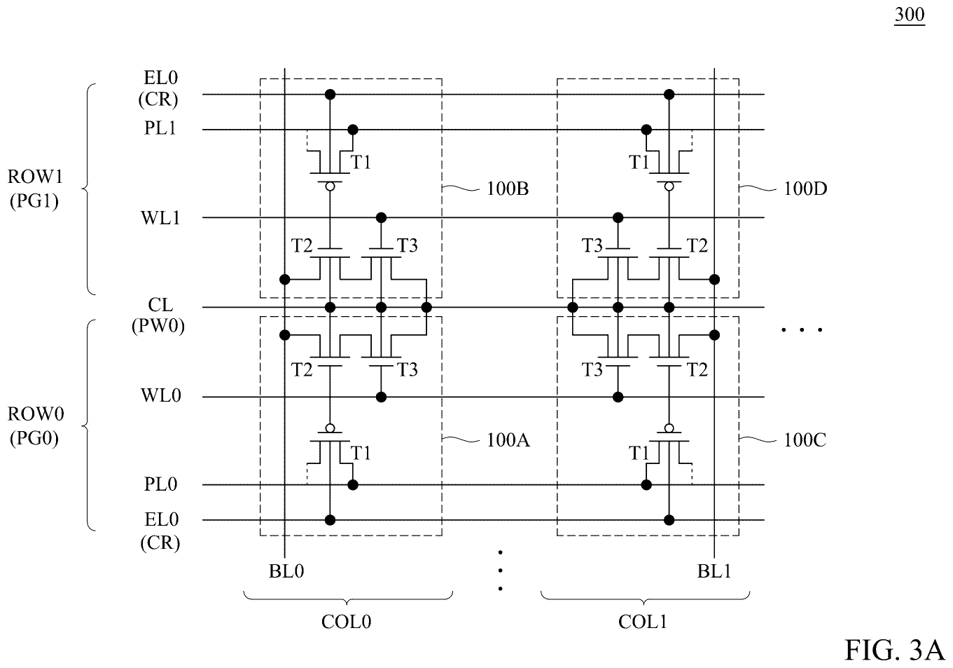

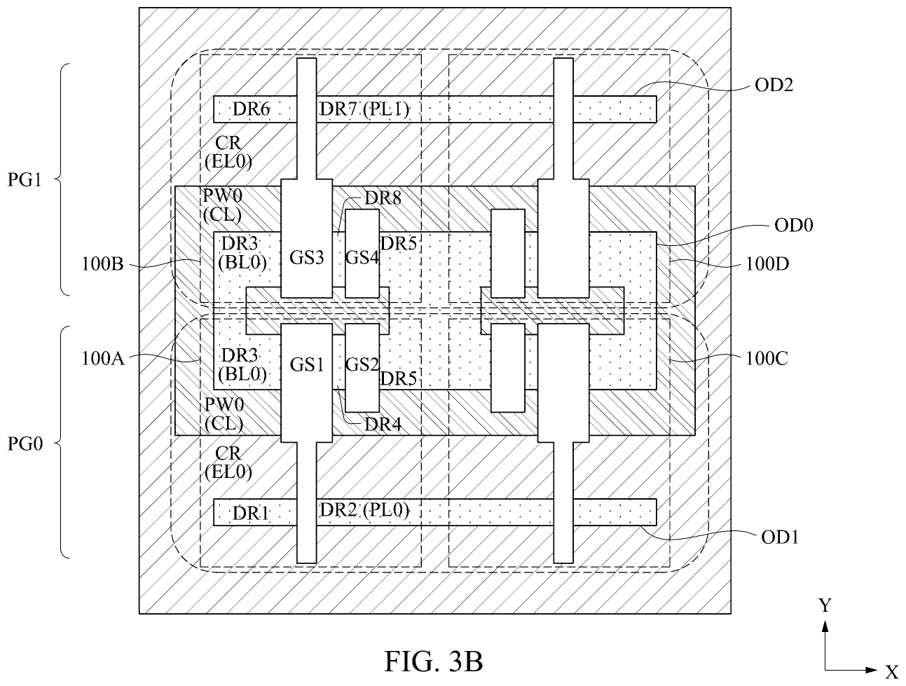

References are made to FIG. 1, FIG. 3A, and FIG. 3B. FIG. 3A is a schematic diagram illustrating a non-volatile memory device 300 with a common deep region CR according to some embodiments of the present disclosure. FIG. 3B is a layout diagram illustrating the non-volatile memory device 300 in FIG. 3A according to some embodiments of the present disclosure.

As illustrated in FIG. 3A, the non-volatile memory device 300 includes multiple memory cells 100A, 100B, 100C, and 100D, a p-well region PW0, a common deep region CR, and active regions OD0, OD1, and OD2 (shown in FIG. 3B). For better understanding, FIG. 3A merely illustrates four memory cells, but the present disclosure is not limited to this quantity. The memory cells 100A-100D are arranged in an array form.

The memory cells 100A and 100B in a column COL0 are connected to a bit line BL0, and the memory cells 100C and 100D in a column COL1 are connected to a bit line BL1. The memory cells 100A and 100C in a row ROW0 are in a page PG0, and the memory cells 100B and 100D in a row ROW1 are in a page PG1. The memory cells 100A and 100C in the row ROW0 are connected to an erase line EL0, a program line PL0, a word line WL0, and a control line CL. The memory cells 100B and 100D in the row ROW1 are connected to the erase line EL0, a program line PL1, a word line WL1, and the control line CL.

Each of the memory cells 100A-100D includes the transistors T1-T3. The transistor T1 of the memory cell 100A is disposed on the common deep region CR connected to the erase line EL0, and the transistors T2-T3 of the memory cell 100A is disposed on a p-well region PW0 connected to the control line CL. The transistor T1 of the memory cell 100B is disposed on the common deep region CR connected to the erase line EL0, and the transistors T2-T3 of the memory cell 100B are disposed on the p-well region PW0 connected to the control line CL. In other words, the memory cell 100A and the memory cell 100B share the common deep region CR connected to the same erase line EL0 and the p-well region PW0 connected to the same control line CL. The other connection relationships of the transistors T1-T3 are similar to those described with FIG. 2A, and therefore their details are not described herein again.

The memory cells 100C and 100D have the similar circuit architectures, so they are not described herein again.

In some embodiments, the common deep region CR is a deep n-well region (DNW). In some embodiment, the common deep region CR is an n-type buried layer (NBL).

Other details about internal architectures of each of the memory cells 100A-100D are the same to those of the memory cell 100 in FIG. 1, so they are not described herein again.

As illustrated in FIG. 3B, the p-well region PW0 is disposed in the common deep region CR, and the active region OD0 is disposed in the p-well region PW0. The active region OD1, the p-well region PW0, and the active region OD2 are arranged in sequence along the direction Y. The p-well region PW0 and the active regions OD0, OD1, and OD2 are extended along a direction X. In addition, the active region OD0 is n-doped and the active regions OD1 and OD2 are p-doped. A gate structure GS1 is disposed on the active regions OD0 and OD1, the common deep region CR, and the p-well region PW0, where the gate structure GS1 is floating. A first part of the gate structure GS1 extends along the direction Y, and partially covers the active region OD0, the p-well region PW0, and the common deep region CR. A second part of the gate structure GS1 extends along the direction Y, and partially covers the common deep region CR and the active region OD1. The first part of the gate structure GS1 has a greater width in comparison with the second part of the gate structure GS1, where the widths of the first part and the second part of the gate structure GS1 are measured along the direction X. A gate structure GS2 is disposed on the p-well region PW0 and the active region OD0, where the gate structure GS2 is connected to the word line WL0. The active region OD1 is divided into doping regions DR1 and DR2 by the second part of the gate structure GS1. The doping region DR1 is disposed in the common deep region CR and at a first side of the second part of the gate structure GS1, where the doping region DR1 is floating or connected to the program line PL0. The doping region DR2 is disposed in the common deep region CR and at a second side of the second part of the gate structure GS1, where the doping region DR2 is connected to the program line PL0. The active region OD0 is divided into doping regions DR3, DR4, and DR5 by the first part of the gate structure GS1 and the gate structure GS2. The doping region DR3 is disposed in the p-well region PW0 and at the first side of the first part of the gate structure GS1, where the doping region DR3 is connected to the bit line BL0. The doping region DR4 is disposed in the p-well region PW0 and between the second side of the first part of the gate structure GS1 and a first side of the gate structure GS2. The doping region DR5 is disposed in the p-well region PW0 and at a second side of the gate structure GS2, where the doping region DR5 is connected to the control line CL via the p-well region PW0.

The second part of the gate structure GS1, the doping region DR1, and the doping region DR2 form the transistor T1 in the memory cell 100A. The first part of the gate structure GS1, the doping region DR3, and the doping region DR4 form the transistor T2 in the memory cell 100A. The gate structure GS2, the doping region DR4, and the doping region DR5 form the transistor T3 in the memory cell 100A. That is, the gate length of the transistor T1 is smaller than the gate length of the transistor T2.

A gate structure GS3 is disposed on the active regions OD0 and OD2, the common deep region CR, and the p-well region PW0, where the gate structure GS3 is floating. A first part of the gate structure GS3 extends along the direction Y, and partially covers the active region OD0, the p-well region PW0, and the common deep region CR. A second part of the gate structure GS3 extends along the direction Y, and partially covers the common deep region CR and the active region OD2. The first part of the gate structure GS3 has a greater width in comparison with the second part of the gate structure GS3, where the widths of the first part and the second part of the gate structure GS3 are measured along the direction X. A gate structure GS4 is disposed on the p-well region PW0 and the active region OD0. The active region OD2 is divided into doping regions DR6 and DR7 by the second part of the gate structure GS3. The doping region DR6 is disposed in the common deep region CR and at a first side of the second part of the gate structure GS3, where the doping region DR6 is floating or connected to the program line PL1. The doping region DR7 is disposed in the common deep region CR and at a second side of the second part of the gate structure GS3, where the doping region DR7 is connected to the program line PL1. The active region OD0 is divided into doping regions DR3, DR8, and DR5 by the first part of the gate structure GS3 and the gate structure GS4. The doping region DR3 is also disposed at the first side of the first part of the gate structure GS3. The doping region DR8 is disposed in the p-well region PW0 and between the second side of the first part of the gate structure GS3 and a first side of the gate structure GS4. The doping region DR5 is also disposed at a second side of the gate structure GS4.

The second part of the gate structure GS3, the doping region DR6, and the doping region DR7 form the transistor T1 in the memory cell 100B. The first part of the gate structure GS3, the doping region DR3, and the doping region DR8 form the transistor T2 in the memory cell 100B. The gate structure GS4, the doping region DR8, and the doping region DR5 form the transistor T3 in the memory cell 100B. That is, the gate length of the transistor T1 is smaller than the gate length of the transistor T2.

The memory cells 100C and 100D have similar layout architectures, so they are not described herein again.

In some related approaches, memory cells of different pages are disposed on different deep regions to connect to different erase lines, and therefore there is a wasted deep region space between the memory cells in different pages.

Compared to the related approaches above, in the present disclosure, the memory cells 100A and 100C in the page PG0 and the memory cells 100B and 100D in the page PG1 share the p-well region PW0 and the common deep region CR to share the control line CL and the erase line EL0. There is no wasted deep region space between the page PG0 and the page PG1. Thus, a more compacted array can be achieved.

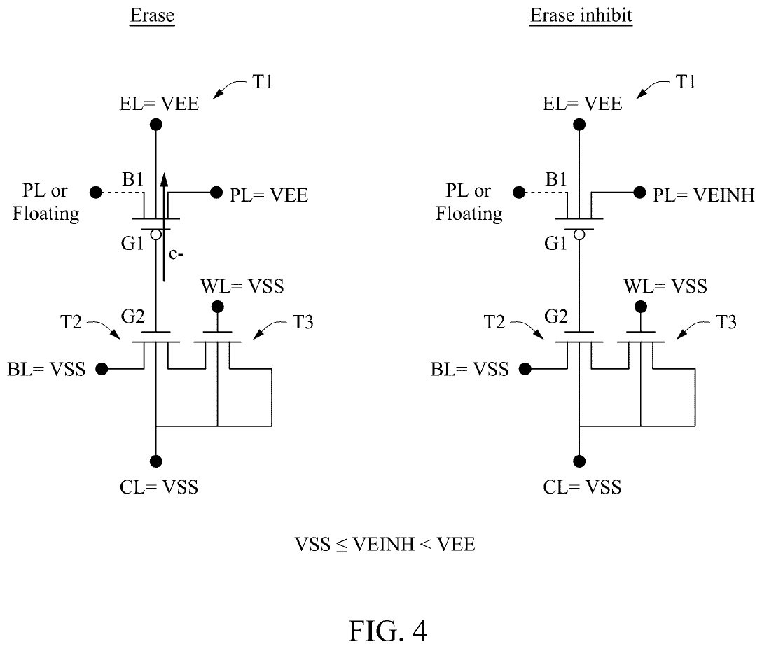

Reference is made to FIG. 4. FIG. 4 is a schematic diagram illustrating an erase operation and an erase inhibit operation on the memory cell 100 in FIG. 1 according to some embodiments of the present disclosure.

As illustrated in FIG. 4, in the erase operation, a voltage VEE is provided to the erase line EL and the program line PL. A voltage VSS is provided to the bit line BL, the control line CL, and the word line WL. The voltage VEE is higher than the voltage VSS. The gate terminal G1 is coupled to a low voltage by the parasitic capacitors of the transistor T2. Thus, there is a voltage difference between the gate terminal G1 and the body terminal B1 gate terminal G2 such that a Fowler-Nordheim (FN) electron tunneling effect occurs and electrons of generated electron-hole pairs are pulled by the voltage VEE and ejected from the gate terminal G1 to the body terminal B1 so as to complete the erase operation.

Compared to the erase operation, a voltage VEINH is provided to the program line PL in the erase inhibit operation. The voltage VEINH is lower than the voltage VEE and is higher than or equal to the voltage VSS. Compared to the voltage VEE, the voltage VEINH is closer to the voltage VSS. The lower voltage VEINH can be transmitted to the channel of the transistor T1 and is used to cancel the voltage difference between the gate terminal G1 and the body terminal B1 in the erase operation. Thus, the erase operation is inhibited.

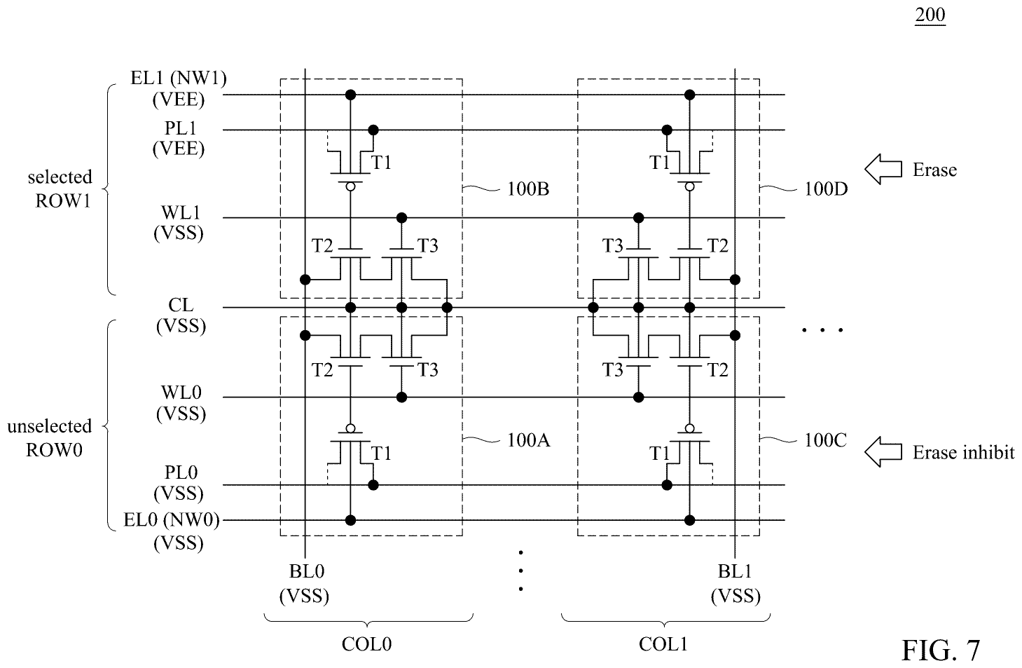

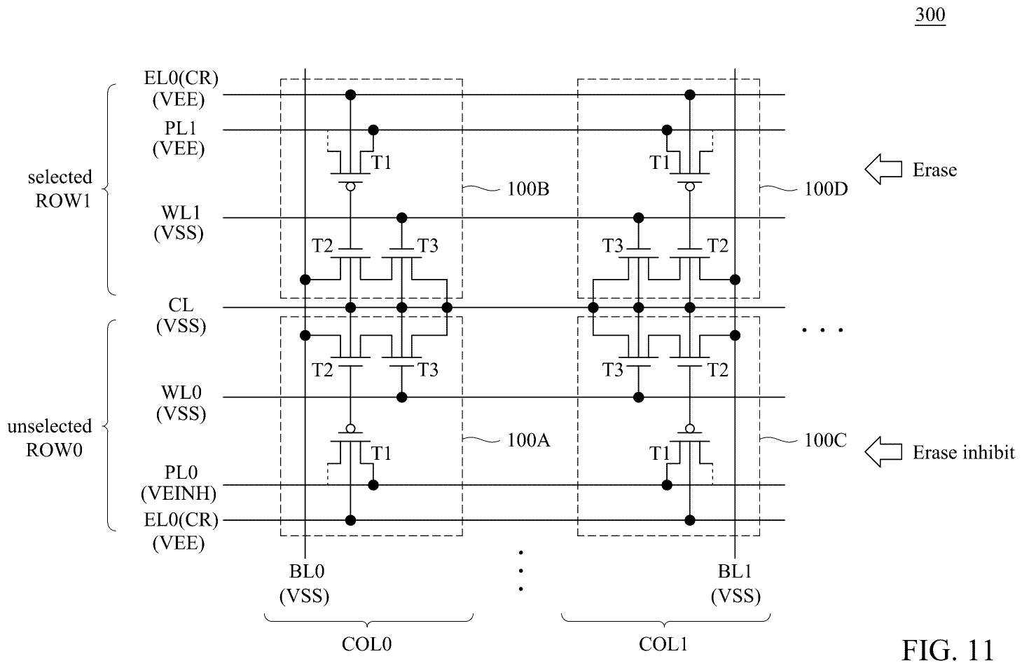

It is noted that the erase inhibit operation shown in FIG. 4 is for the memory cell 100 implemented with the common deep region CR. The voltage VSS is provided to the program line PL and the erase line EL in the erase inhibit operation when the memory cell 100 is implemented without the common deep region CR. The details about these are described in following paragraphs with reference to FIG. 7 and FIG. 11.

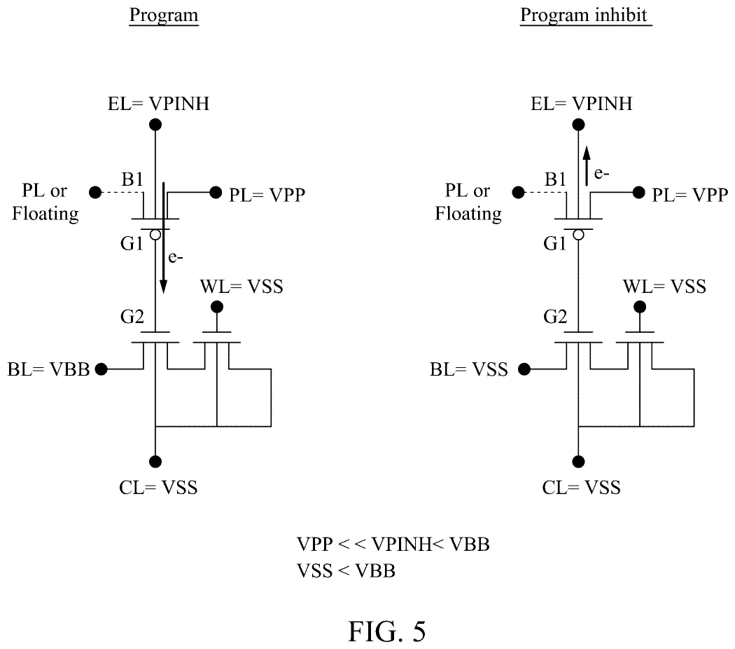

Reference is made to FIG. 5. FIG. 5 is a schematic diagram illustrating a program operation and a program inhibit operation on the memory cell 100 in FIG. 1 according to some embodiments of the present disclosure.

As illustrated in FIG. 5, in the program operation, a voltage VPINH is provided to the erase line EL. A voltage VPP is provided to the program line PL. A voltage VBB is provided to the bit line BL. The voltage VSS is provided to the control line CL and the word line WL. The voltage VPINH is much higher than the voltage VPP such that a band-to-band tunneling induced hot electrons (BBHE) are generated. In addition, the voltage VPINH is lower than the voltage VBB, and the voltage VBB is higher than the voltage VSS. The gate terminal G1 is coupled to a high voltage by the parasitic capacitors of the transistor T2. Thus, there is a voltage difference between the gate terminal G1 and the body terminal B1 such that the electrons are pulled by the high voltage and injected from the body terminal B1 into the gate terminal G1 so as to complete the program operation.

Compared to the program operation, the voltage VSS is provided to the bit line BL in the program inhibit operation. The gate terminal G1 is coupled to a low voltage by the parasitic capacitors of the transistor T2. Since the voltage VPINH is higher than the voltage VSS, the electrons are pulled by the voltage VPINH to the body terminal B1. Thus, the program operation is inhibited.

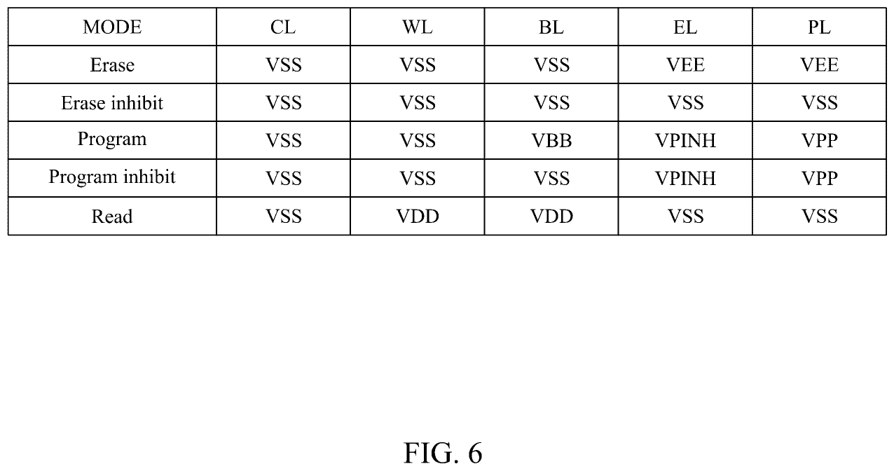

Reference is made to FIG. 6. FIG. 6 is a schematic diagram illustrating voltages under different operations on the non-volatile memory device 200 without the common deep region CR in FIG. 2A according to some embodiments of the present disclosure.

Reference is made to FIG. 7. FIG. 7 is a schematic diagram illustrating an erase operation and an erase inhibit operation on the non-volatile memory device 200 without the common deep region CR in FIG. 2A according to some embodiments of the present disclosure.

As illustrated in FIG. 6 and FIG. 7, the erase operation is performed on the memory cells 100B and 100D in the selected row ROW1. Thus, similar to the embodiments of FIG. 4, the voltage VEE is provided to the erase line EL1 and the program line PL1. The voltage VSS is provided to the word line WL1, the control line CL, the bit line BL0, and the bit line BL1.

In addition, the erase inhibit operation is performed on the memory cells 100A and 100C in the unselected row ROW0. It is noted that since this example is without the common deep region CR, the erase line EL0 and the erase line EL1 are not connected together and thus the voltage VSS is provided to the erase line EL0. In addition, the voltage VSS is also provided the program line PL0, and the word line WL0.

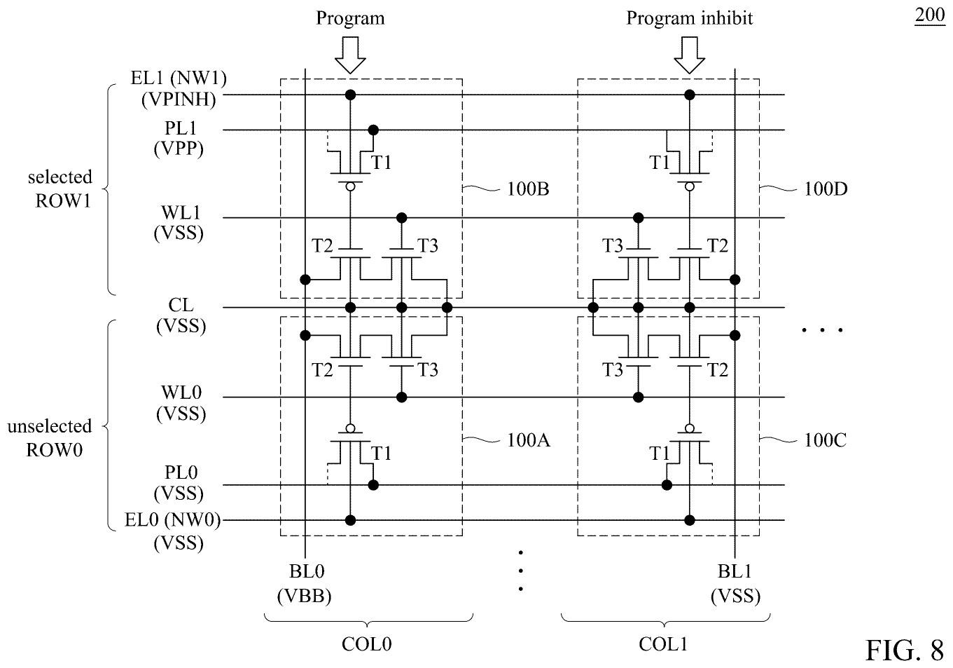

Reference is made to FIG. 8. FIG. 8 is a schematic diagram illustrating a program operation and a program inhibit operation on the non-volatile memory device 200 without the common deep region CR in FIG. 2A according to some embodiments of the present disclosure.

As illustrated in FIG. 6 and FIG. 8, the program operation is performed on the memory cell 100B in the selected row ROW1 and the column COL0. Thus, similar to the embodiments of FIG. 5, the voltage VPINH is provided to the erase line EL1. The voltage VPP is provided to the program line PL1. The voltage VBB is provided to the bit line BL0. The voltage VSS is provided to the word line WL1 and the control line CL.

The program inhibit operation is performed on the memory cell 100D in the selected row ROW1 and the column COL1. Thus, similar to the embodiments of FIG. 5, the voltage VSS is provided to the bit line BL1.

In the unselected row ROW0, the voltage VSS is provided to the word line WL0, the program line PL0, and the erase line EL0.

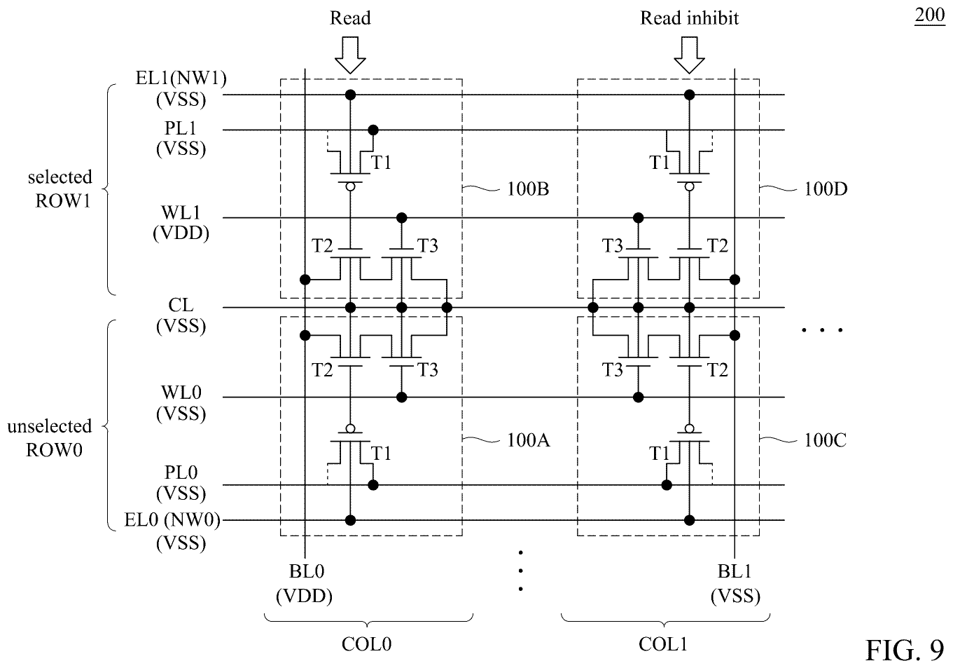

Reference is made to FIG. 9. FIG. 9 is a schematic diagram illustrating a read operation and a read inhibit operation on the non-volatile memory device 200 without the common deep region CR in FIG. 2A according to some embodiments of the present disclosure.

As illustrated in FIG. 6 and FIG. 9, the read operation is performed on the memory cell 100B in the selected row ROW1 and the column COL0, and the read inhibit operation is performed on the memory cell 100D in the selected row ROW1 and the column COL1. Thus, a voltage VDD is provided to the word line WL1 and the bit line BL0. The voltage VSS is provided to the erase line EL1, the program line PL1, the control line CL, and the bit line BL1. The voltage VDD is higher than the voltage VSS.

In the unselected row ROW0, the voltage VSS is provided to the word line WL0, the program line PL0, and the erase line EL0.

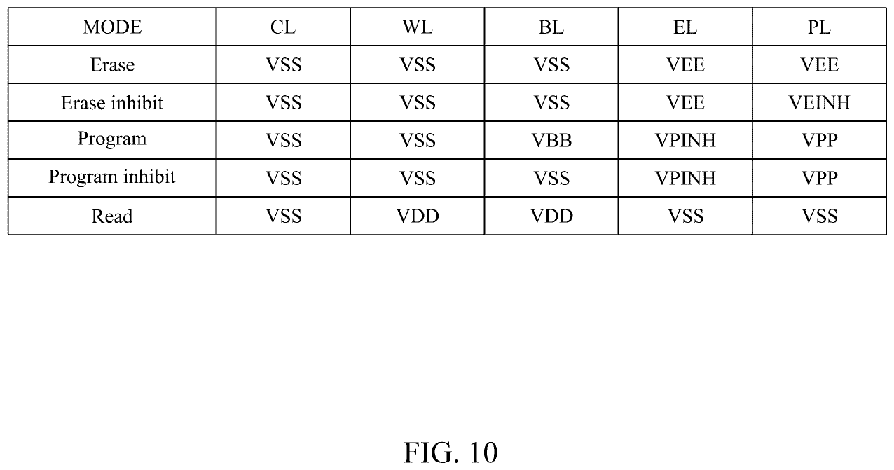

Reference is made to FIG. 10. FIG. 10 is a schematic diagram illustrating voltages under different operations on the non-volatile memory device 300 with the common deep region CR in FIG. 3A according to some embodiments of the present disclosure.

Reference is made to FIG. 11. FIG. 11 is a schematic diagram illustrating an erase operation and an erase inhibit operation on the non-volatile memory device 300 with the common deep region CR in FIG. 3A according to some embodiments of the present disclosure.

As illustrated in FIG. 10 and FIG. 11, the erase operation is performed on the memory cells 100B and 100D in the selected row ROW1. Thus, similar to the embodiments of FIG. 4, the voltage VEE is provided to the erase line EL0 and the program line PL1. The voltage VSS is provided to the word line WL1, the control line CL, the bit line BL0, and the bit line BL1.

In addition, the erase inhibit operation is performed on the memory cells 100A and 100C in the unselected row ROW0. It is noted that since this example is with the common deep region CR, the memory cells 100A-100D share the same erase line EL0 receiving the voltage VEE. In addition, similar to the embodiments of FIG. 4, the voltage VEINH is provided the program line PL0 and the voltage VSS is provided to the word line WL0.

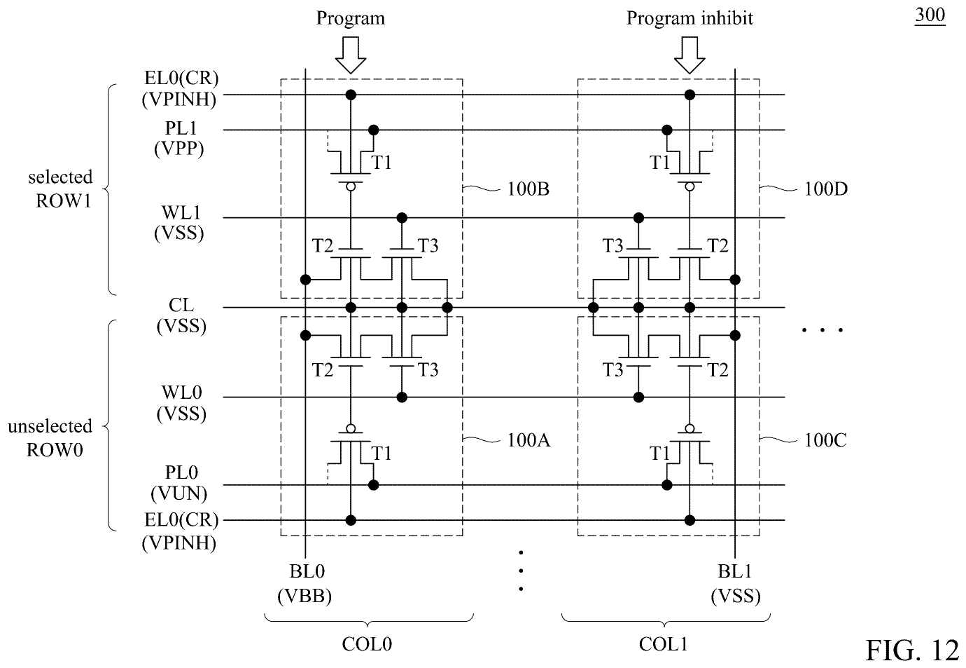

Reference is made to FIG. 12. FIG. 12 is a schematic diagram illustrating a program operation and a program inhibit operation on the non-volatile memory device 300 with the common deep region CR in FIG. 3A according to some embodiments of the present disclosure.

As illustrated in FIG. 10 and FIG. 12, the program operation is performed on the memory cell 100B in the selected row ROW1 and the column COL0. Thus, similar to the embodiments of FIG. 5, the voltage VPINH is provided to the erase line EL0. The voltage VPP is provided to the program line PL1. The voltage VSS is provided to the word line WL1 and the control line CL. The voltage VBB is provided to the bit line BL0.

The program inhibit operation is performed on the memory cell 100D in the selected row ROW1 and the column COL1. Thus, similar to the embodiments of FIG. 5, the voltage VSS is provided to the bit line BL1.

In the unselected row ROW0, the voltage VSS is provided to the word line WL0. A voltage VUN is provided to the program line PL0. It is noted that since this example is with the common deep region CR, the memory cells 100A-100D share the same erase line EL0 receiving the voltage VPINH. The voltage VUN is higher than the voltage VPP and is lower than or equal to the voltage VPINH. Compared to the voltage VPP, the voltage VUN is closer to the voltage VPINH. Thus, a voltage difference between the voltage VPINH and the voltage VUN is small enough such that BBHE tunneling effect does not occur (there is no electron-hole pair).

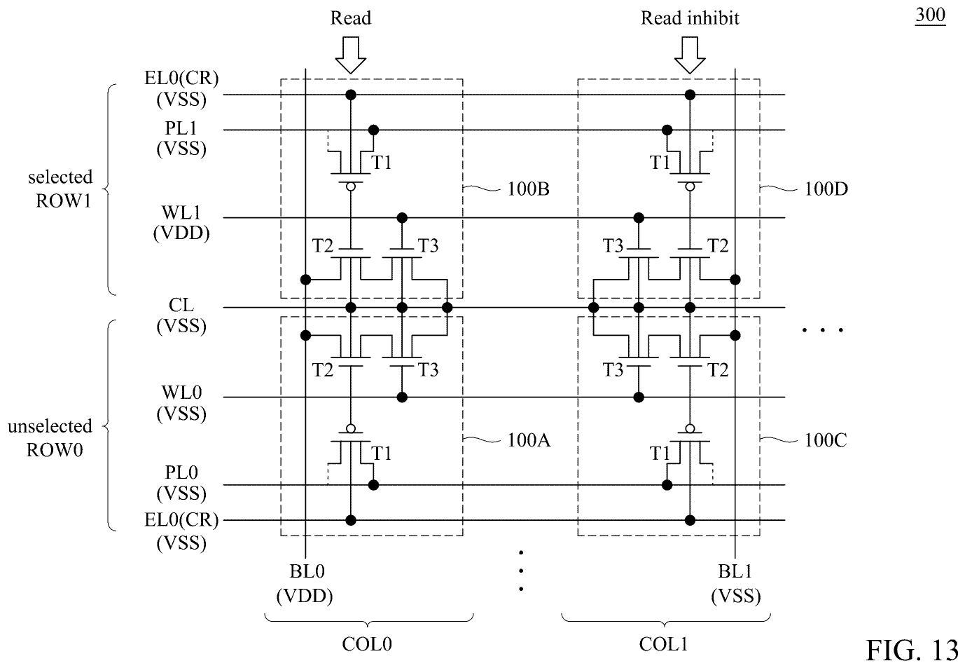

Reference is made to FIG. 13. FIG. 13 is a schematic diagram illustrating a read operation and a read inhibit operation on the non-volatile memory device 300 with the common deep region in FIG. 3A according to some embodiments of the present disclosure.

As illustrated in FIG. 10 and FIG. 13, the read operation is performed on the memory cell 100B in the selected row ROW1 and the column COL0, and the read inhibit operation is performed on the memory cell 100D in the selected row ROW1 and the column COL1. Thus, the voltage VDD is provided to the word line WL1 and the bit line BL0. The voltage VSS is provided to the erase line EL0, the program line PL1, the control line CL, and the bit line BL1.

In the unselected row ROW0, the voltage VSS is provided to the word line WL0 and the program line PL0. It is noted that since this example is with the common deep region CR, the memory cells 100A-100D share the same erase line EL0 receiving the voltage VSS.

Based on the descriptions above, in the present disclosure, the memory cell and the non-volatile memories have the advantages of size reduction, endurance improvement, low-voltage read operation, and other read benefits.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory cell, comprising:
a first transistor, comprising:
a body terminal connected to an erase line;
a first source/drain terminal connected to a program line;
a second source/drain terminal; and
a gate terminal;
a second transistor, comprising:
a body terminal connected to a control line;
a first source/drain terminal connected to a bit line;
a second source/drain terminal; and
a gate terminal connected to the gate terminal of the first transistor; and
a third transistor, comprising:
a body terminal connected to the control line;
a first source/drain terminal connected to the control line;
a second source/drain terminal connected to the second source/drain terminal of the second transistor; and
a gate terminal connected to a word line,
wherein the gate terminal of the first transistor and the gate terminal of the second transistor are floating,
wherein when a program operation is performed on the memory cell, electrons are injected from the body terminal of the first transistor into the gate terminal of the first transistor,
wherein when a read operation is performed on the memory cell, the first source/drain terminal of the second transistor provides a read current to the bit line.

2. The memory cell of claim 1, wherein the second source/drain terminal of the first transistor is connected to the program line or is floating.

3. The memory cell of claim 1, wherein the first transistor is p-type, and the second transistor and the third transistor are n-type.

4. The memory cell of claim 1, wherein when an erase operation is performed on the memory cell, a first voltage is provided to the erase line and the program line, a second voltage is provided to the bit line, the control line, and the word line so that a Fowler-Nordheim electron tunneling effect occurs to pull the electrons from the gate terminal of the first transistor to the body terminal of the first transistor,
wherein the first voltage is higher than the second voltage.

5. The memory cell of claim 4, wherein when an erase inhibit operation is performed on the memory cell, the first voltage is provided to the erase line, the second voltage is provide to the control line, the word line, and the bit line, and a third voltage is provided to the program line,
wherein the third voltage is lower than the first voltage and is higher than or equal to the second voltage.

6. The memory cell of claim 4, wherein when an erase inhibit operation is performed on the memory cell, the second voltage is provided to the erase line, the program line, the word line, the control line, and the bit line.

7. The memory cell of claim 1, wherein when the program operation is performed on the memory cell, a first voltage is provided to the erase line, a second voltage is provided to the program line, a third voltage is provided to the bit line, and a fourth voltage is provided to the control line and the word line so that band-to-band tunneling induced hot electrons are generated as the electrons injected into the gate terminal of the first transistor,
wherein the first voltage is higher than the second voltage and is lower than the third voltage, wherein the third voltage is higher than the fourth voltage.

8. The memory cell of claim 7, wherein when a program inhibit operation is performed on the memory cell, the first voltage is provided to the erase line, the second voltage is provided to the program line, and the fourth voltage is provided to the bit line, the control line, and the word line,
wherein the first voltage is higher than the second voltage, wherein the first voltage is higher than the fourth voltage.

9. A non-volatile memory device, comprising:
a first well region;
a second well region;
a third well region; and
a plurality of memory cells, wherein each memory cell comprises a first transistor, a second transistor, and a third transistor, wherein a gate terminal of the first transistor and a gate terminal of the second transistor are mutually coupled and are floating, and the second transistor and the third transistor are coupled in series,
wherein a first memory cell of the plurality of memory cells is in a first page, wherein the first transistor in the first memory cell is disposed on the first well region, and the second transistor and the third transistor in the first memory cell are disposed on the second well region, and
wherein a second memory cell of the plurality of memory cells is in a second page, wherein the first transistor in the second memory cell is disposed on the third well region, and the second transistor and the third transistor in the second memory cell are disposed on the second well region.

10. The non-volatile memory device of claim 9, wherein the first memory cell comprises:
a first gate structure disposed on the first well region and the second well region, and comprising a first part and a second part;
a second gate structure disposed on the second well region;
a first doping region disposed in the first well region and at a first side of the second part of the first gate structure;
a second doping region disposed in the first well region and at a second side of the second part of the first gate structure;
a third doping region disposed in the second well region and at a first side of the first part of the first gate structure;
a fourth doping region disposed in the second well region and between a second side of the first part of the first gate structure and a first side of the second gate structure; and
a fifth doping region disposed on the second well region and at a second side of the second gate structure,
wherein along a lateral direction of the first well region, a width of the first part of the first gate structure is greater than a width of the second part of the first gate structure.

11. The non-volatile memory device of claim 10, wherein the first gate structure, the first doping region, and the second doping region form the first transistor in the first memory cell,
wherein the first gate structure, the third doping region, and the fourth doping region form the second transistor in the first memory cell,
wherein the second gate structure, the fourth doping region, and the fifth doping region form the third transistor in the first memory cell,
wherein a gate length of the first transistor of the first memory cell is smaller than a gate length of the second transistor of the first memory cell.

12. The non-volatile memory device of claim 10, wherein the second memory cell comprises:
a third gate structure disposed on the third well region and the second well region, and comprising a first part and a second part;
a fourth gate structure disposed on the second well region;
a sixth doping region disposed in the third well region and at a first side of the second part of the third gate structure;
a seventh doping region disposed in the third well region and at a second side of the second part of the third gate structure, wherein the third doping region is disposed at a first side of the first part of the third gate structure; and
an eighth doping region disposed in the second well region and between a second side of the first part of the third gate structure and a first side of the fourth gate structure, wherein the fifth doping region is disposed at a second side of the fourth gate structure,
wherein along the lateral direction of the first well region, a width of the first part of the third gate structure is greater than a width of the second part of the third gate structure.

13. The non-volatile memory device of claim 12, wherein the third gate structure, the sixth doping region, and the seventh doping region form the first transistor in the second memory cell,
wherein the third gate structure, the third doping region, and the eighth doping region form the second transistor in the second memory cell,
wherein the fourth gate structure, the eighth doping region, and the fifth doping region form the third transistor in the second memory cell,
wherein a gate length of the first transistor of the second memory cell is smaller than a gate length of the second transistor of the second memory cell.

14. A non-volatile memory device, comprising:
a common deep region;
a well region disposed in the common deep region; and
a plurality of memory cells, wherein each memory cell comprises a first transistor, a second transistor, and a third transistor, wherein a gate terminal of the first transistor and a gate terminal of the second transistor are mutually coupled and are floating, and the second transistor and the third transistor are coupled in series,
wherein a first memory cell of the plurality of memory cells is in a first page, wherein the first transistor in the first memory cell is disposed on the common deep region, and the second transistor and the third transistor in the first memory cell are disposed on the well region; and
wherein a second memory cell of the plurality of memory cells is in a second page, wherein the first transistor in the second memory cell is disposed on the common deep region, and the second transistor and the third transistor in the second memory cell are disposed on the well region.

15. The non-volatile memory device of claim 14, wherein the common deep region is a deep n-well region.

16. The non-volatile memory device of claim 14, wherein the common deep region is an n-type buried layer.

17. The non-volatile memory device of claim 14, wherein the first memory cell comprises:
a first gate structure disposed on the common deep region and the well region, and comprising a first part and a second part;
a second gate structure disposed on the well region;
a first doping region disposed in the common deep region and at a first side of the second part of the first gate structure;
a second doping region disposed in the common deep region and at a second side of the second part of the first gate structure;
a third doping region disposed in the well region and at a first side of the first part of the first gate structure;
a fourth doping region disposed in the well region and between a second side of the first part of the first gate structure and a first side of the second gate structure; and
a fifth doping region disposed on the well region and at a second side of the second gate structure,
wherein along a lateral direction of the well region, a width of the first part of the first gate structure is greater than a width of the second part of the first gate structure.

18. The non-volatile memory device of claim 17, wherein the first gate structure, the first doping region, and the second doping region form the first transistor in the first memory cell,
wherein the first gate structure, the third doping region, and the fourth doping region form the second transistor in the first memory cell,
wherein the second gate structure, the fourth doping region, and the fifth doping region form the third transistor in the first memory cell,
wherein a gate length of the first transistor of the first memory cell is smaller than a gate length of the second transistor of the first memory cell.

19. The non-volatile memory device of claim 17, wherein the second memory cell comprises:
a third gate structure disposed on the common deep region and the well region, and comprising a first part and a second part;
a fourth gate structure disposed on the well region;
a sixth doping region disposed in the common deep region and at a first side of the second part of the third gate structure;
a seventh doping region disposed in the common deep region and at a second side of the second part of the third gate structure, wherein the third doping region is disposed at a first side of the first part of the third gate structure; and
an eighth doping region disposed in the well region and between a second side of the first part of the third gate structure and a first side of the fourth gate structure, wherein the fifth doping region is disposed at a second side of the fourth gate structure,
wherein along the lateral direction of the well region, a width of the first part of the third gate structure is greater than a width of the second part of the third gate structure.

20. The non-volatile memory device of claim 19, wherein the third gate structure, the sixth doping region, and the seventh doping region form the first transistor in the second memory cell,
wherein the third gate structure, the third doping region, and the eighth doping region form the second transistor in the second memory cell,
wherein the fourth gate structure, the eighth doping region, and the fifth doping region form the third transistor in the second memory cell,
wherein a gate length of the first transistor of the second memory cell is smaller than a gate length of the second transistor of the second memory cell.
